(19) United States
(12) Patent Application Publication
(10) Pub. No.: US 2024/0145450 A1
(43) Pub. Date: May 2, 2024

(54) PACKAGE EDGE PASSIVE COMPONENT ARRAY FOR IMPROVED POWER INTEGRITY

(71) Applicant: Intel Corporation, Santa Clara, CA (US)

(72) Inventors: Chin Lee KUAN, Bentong (MY); Bok Eng CHEAH, Gelugor (MY); Jackson Chung Peng KONG, Tanjung Tokong (MY); Amit JAIN, Sherwood, OR (US); Sameer SHEKHAR, Portland, OR (US)

(21) Appl. No.: 18/050,527

(22) Filed: Oct. 28, 2022

(51) Int. Cl. H01L 25/16; H01L 21/48; H01L 23/00; H01L 23/498

(52) U.S. Cl. CPC H01L 25/162; H01L 21/4853; H01L 23/49816; H01L 23/49833; H01L 23/562

(57) ABSTRACT

The present disclosure generally relates to an electronic assembly. The electronic assembly may include a semiconductor package including a first surface, an opposing second surface, and a side wall. The electronic assembly may also include a printed circuit board coupled to the second surface of the semiconductor package. The electronic assembly may further include at least one passive component array including one or more passive components at least partially embedded in a mold layer, each passive component further including a first terminal and a second terminal, wherein the first terminal of the passive component may be coupled to the printed circuit board and the passive component array may be attached to the side wall of the semiconductor package.

### BACKGROUND

There are challenges in addressing escalating power integrity requirements for high performance computing devices. Due to package and motherboard mechanical warpage concerns, corner glue and/or edge glue may be introduced on mobile platforms to enhance system stiffness. This may lead to additional printed circuit board (PCB) keep-out-zone (KOZ) requirements, which may impose restrictions on platform component placements as well as power delivery design. No platform component may be allowed within the corner glue and/or edge glue KOZ. Hence, PCB capacitors may be placed at least 2 mm further from a package edge, resulting in power integrity loadline and Vmin performance degradation as well as system form factor tradeoff due to increased board area.

Current solutions to address the above-mentioned challenges include:
a) introduction of additional board/platform level capacitors for power delivery network (PDN) impedance suppression;
b) introduction of costly small form-factor multi-layer ceramic capacitors (MLCC) for device miniaturization;
c) introduction of MLCCs on package top side (e.g., die-side capacitor) and/or bottom side (e.g., land-side capacitor); or
d) use of silicon MIM capacitance (MIMCap) on active die and/or passive interposers.

The disadvantages of the above-mentioned solutions may include, but not limited to, increased system/silicon Bill of Materials (BOM) costs, increased package and/or PCB form-factor and increased device z-height profile (thickness) that prohibit device miniaturization.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1A shows a cross-sectional view of an electronic assembly according to an aspect of the present disclosure;

FIG. 1B shows a top view layout of the electronic assembly according to the aspect as shown in FIG. 1A;

FIGS. 2A through 2H show cross-sectional views directed to an exemplary simplified process flow for forming an electronic assembly according to an aspect that is generally similar to that shown in FIG. 1A of the present disclosure;

FIG. 3 shows an illustration of a computing device that includes an electronic assembly according to a further aspect of the present disclosure; and

FIG. 4 shows a flow chart illustrating a method for forming an electronic assembly according to an aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects may be combined with one or more other aspects to form new aspects.

Present disclosure attempts to address the power integrity loadline and Vmin performance degradation as well as system form factor tradeoff due to increased board area.

Technical advantages of the present disclosure may include, but not limited to:
i) AC noise mitigation (Vmin improvements and impedance loadline reduction) that contribute to increased signal transmission data-rate and computing Core or Graphics Fmax performance gain.
ii) reduced BOM cost and area for low decoupling cost and system miniaturization.
iii) reduced package form factor since use of package die-side or land-side capacitors to make up capacitance needed for performance can be avoided.
iv) the total amount of capacitors required to achieve iso-performance to conventional solution can be reduced, e.g., an increase of capacitor component count to compensate the degraded decoupling effectiveness due to corner glue KOZ requirements can be avoided. Apart from decoupling capacitors, other platform components such as RCOMP for signal termination and inductors for noise filtering mechanisms may likewise be used.

The present disclosure generally relates to a device, e.g., an electronic assembly. The electronic assembly may include a semiconductor package including a first surface, an opposing second surface, and a side wall. The electronic assembly may also include a printed circuit board coupled to the second surface of the semiconductor package. The electronic assembly may further include at least one passive component array including one or more passive components at least partially embedded in a mold layer, each passive component further including a first terminal and a second terminal, wherein the first terminal of the passive component may be coupled to the printed circuit board and the passive component array may be attached to the side wall of the semiconductor package.

The present disclosure also generally relates to a computing device. The computing device may include a printed circuit board and an electronic assembly coupled to the printed circuit board. The electronic assembly may include a semiconductor package including a first surface, an opposing second surface, and a side wall, wherein the second surface of the semiconductor package may be coupled to the printed circuit board. The electronic assembly may also include at least one passive component array including one or more passive components at least partially embedded in a mold layer, each passive component further including a first terminal and a second terminal, wherein the first terminal of the passive component may be coupled to the printed circuit board and the passive component array may be attached to the side wall of the semiconductor package.

The present disclosure further generally relates to a method. The method may include forming a semiconductor package including a first surface, an opposing second surface, and a side wall. The method may also include coupling the second surface of the semiconductor package to a printed circuit board. The method may further include forming at least one passive component array including one or more passive components at least partially embedded in a mold layer, each passive component further including a first terminal and a second terminal. The method may also further include coupling the first terminal of the passive component to the printed circuit board and attaching the passive component array to the side wall of the semiconductor package.

To more readily understand and put into practical effect the present disclosure, particular aspects will now be described by way of examples and not limitations, and with reference to the drawings. For the sake of brevity, duplicate descriptions of features and properties may be omitted.

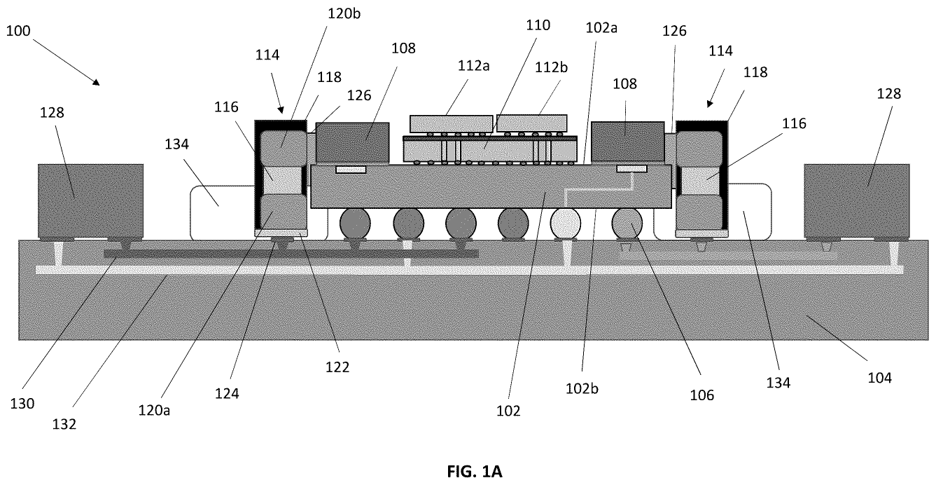

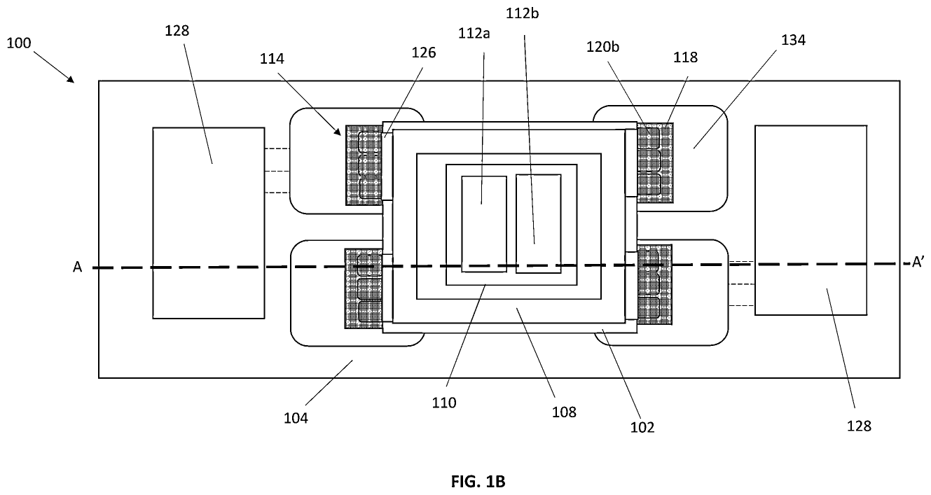

FIG. 1A shows a cross-sectional view of an electronic assembly according to an aspect of the present disclosure. In this illustration, it is shown an electronic assembly 100 (or a semiconductor package), e.g., a stacked die package or a multichip package (MCP) with one or more package edge capacitor arrays for improved power integrity and device miniaturization. The cross-section is taken along the A-A′ line of FIG. 1B.

The term “multichip package” generally refers to an electronic assembly that may include two or more dies, chips, or chiplets (interchangeably used herein) that may be arranged laterally along the same plane.

In various aspects, the electronic assembly 100 may include a semiconductor package including a package substrate 102. In various aspects, the package substrate 102 may be, e.g., an organic substrate or a ceramic substrate. The package substrate 102 may include a first surface 102a and an opposing second surface 102b. The package substrate 102 may include contact pads, electrical interconnects and routings, and other features, which may or may not be shown in any of the present figures and which are conventional features known to a person skilled in the art.

The electronic assembly 100 may further include a printed circuit board (PCB) 104. The PCB 104 may be coupled to the second surface 102b of the package substrate 102 via a ball grid array (BGA) 106 including an array of electrically conducting balls.

In various aspects, the electronic assembly 100 may further include a stiffener 108. The stiffener 108 may be disposed on or coupled to the first surface 102a of the package substrate 102. In the aspect shown in FIG. 1A, the stiffener 108 may be located at or proximal to (i.e., near) an edge of the package substrate 102. In the aspect shown in FIG. 1A, the stiffener may include a side surface that is proximal to a side wall of the package substrate 102. The stiffener 108 may include, for example, an aluminum layer, a stainless-steel layer, or an organic layer coated with a conductive layer such as copper.

Various other components may be disposed on or coupled to the first surface 102a of the package substrate 102. In the aspect shown in FIG. 1A, a base die 110 and one or more chiplets (112a, 112b) may be coupled to the package substrate 102. In the aspect shown in FIG. 1A, the one or more chiplets (112a, 112b) may be coupled to the package substrate 102 through the base die 110 such as a silicon interposer. The base die 110 and the one or more chiplets (112a, 112b) may be located within a perimeter of the stiffener 108 as illustrated in FIG. 1A. The one or more chiplets (112a, 112b) may include, for example, a central processing unit (CPU), a system-on-chip (SOC), a graphic processing unit (GPU), a deep learning processor (DLP), or a neural network processor (NNP).

In various aspects, the electronic assembly 100 may further include one or more package edge capacitor arrays 114 for improved power integrity (PI) performance and device miniaturization. The package edge capacitor array 114 may be positioned in close proximity or next to an edge of the package substrate 102. In the aspect shown in FIG. 1A, the package edge capacitor array 114 may be adjacent the stiffener 108. The package edge capacitor array 114 may at least partially surround a periphery of the package substrate 102.

In various aspects, the package edge capacitor array 114 may include one or more capacitor components 116. The capacitor component 116 may be at least partially embedded in a mold layer 118. In the aspect shown in FIG. 1A, the capacitor component 116 may be rectangular, though not necessarily so. Other shapes of the capacitor component 116 may also be used. Examples of suitable mold layer materials may include, but not limited to, an epoxy polymer resin layer, a silicone layer, a polyimide layer, or a polycarbonate layer.

In various aspects, the capacitor component 116 may include a first terminal 120a and an opposing second terminal 120b. In the aspect shown in FIG. 1A, the capacitor component 116 may be embedded in the mold layer 118 such that a portion of the first terminal 120a and a portion of the second terminal 120b may not be embedded (i.e., exposed) in the mold layer 118. The first terminal 120a may be coupled to the PCB 104 through a terminal pad 122 and a first solder layer 124 at the PCB side. In a further aspect, the first terminal 120a of the capacitor component 116 may be further coupled to the base die 110 and one or more chiplets (112a, 112b) through the second surface of the package substrate 102. The second terminal 120b may be coupled to the stiffener 108 located at or near the edges of the package substrate 102 via a second solder layer 126. In the aspect shown in FIG. 1A, the second terminal 120b may be coupled to a side surface of the stiffener 108 that may be facing the second terminal 120b. In other words, the connection between the first terminal 120a and the PCB 104 may be approximately perpendicular (though not necessarily so) to the connection between the second terminal 120b and the stiffener 108. Examples of suitable solder layer may include, but not limited to, tin-silver (SnAg) composites or tin-silver-copper (SnAgCu) composites.

In various aspects, the electronic assembly 100 may further include a binding material 134, e.g., a glue, located on and adhered to the PCB 104 at one or more corners of the package substrate 102 to enhance stiffness of the electronic assembly 100. The binding material 134 may at least partially encapsulate the package edge capacitor array 114. Unlike a conventional electronic assembly, by attaching the capacitor array 114 to the stiffener 108, capacitor components 116 may be located within the corner glue keep-out-zone, thereby enhancing power integrity performance and device miniaturization. Examples of suitable glue materials may include, but not limited to, light curable acrylics, cationic epoxies, thermal curable acrylates, polyester resin, or polyurethane resin.

In an aspect, the second terminal 120b may extend away from the PCB 104 by a first height ranging from 150 μm to 500 μm.

In an aspect, the stiffener 108 may be configured away from the PCB 104 by a second height ranging from 100 μm to 400 μm.

In various aspects, the first terminal 120a may be coupled to a voltage regulator 128 and to the package substrate 102 through a board routing, solder layer and/or solder ball (collectively, 130) for a reduced AC loop inductance and/or noise mitigation for the power delivery to the one or more chiplets (112a, 112b). In an aspect, the first terminal 120a may be associated with a power supply voltage (Vcc), e.g., a 0.5V supply, a 1.0V supply, or a 3.3.V supply. In further aspects, the voltage regulator 128 may be further coupled to the first terminal 120a of the capacitor component 116 and to the second surface of the package substrate 102.

In various aspects, the second terminal 120b and the stiffener 108 may be associated with a ground reference voltage (Vss). The stiffener 108 may be coupled to the ground reference voltage (Vss) plane in the package substrate 102 through one or more package contact pads and a conductive layer, e.g., a solder layer or a conductive adhesive layer (collectively, 132).

It is to be understood and appreciated that while the present discussion may relate to an array including one or more capacitor components, other passive components such as resistors and inductors for signal termination or noise LC filtering purposes may likewise be used. In other words, in addition to a package edge capacitor array, a package edge resistor array or a package edge inductor array may also be used.

FIG. 1B shows a top view layout of the electronic assembly 100 according to the aspect as shown in FIG. 1A. Each of the package substrate 102, PCB 104, stiffener 108, base die 110, first and second chiplets (112a, 112b), package edge capacitor arrays 114, mold layer 118, second terminal 120b, second solder layer 126, voltage regulator 128, and binding material 134 may include a footprint or perimeter.

In the aspect shown in FIG. 1B, the footprint of the first and second chiplets (112a, 112b) may fall within the perimeter of the base die 110. The footprints of the base die 110 and the stiffener 108 may fall within the perimeter of the package substrate 102. While the stiffener 108 may be shown to be completely peripheral to the package substrate 102, in other aspects, the stiffener 108 may be partially peripheral to the package substrate 102. For example, the stiffener 108 may only be located near the corners of the package substrate 102.

In this top view, the footprint of the package edge capacitor arrays 114 may fall within the perimeter of the binding material 134. In other words, each package edge capacitor array 114 may be encapsulated by a respective binding material 134. Each package edge capacitor array 114 may be seen to at least partially surround a periphery of the package substrate 102. The second terminal 120b may be coupled to the second solder layer 126.

The footprints of the package substrate 102, stiffener 108, base die 110, first and second chiplets (112a, 112b), package edge capacitor arrays 114, mold layer 118, second terminal 120b, second solder layer 126, voltage regulator 128, and binding material 134 may all fall within the perimeter of the PCB 104.

In the aspect shown in FIG. 1B, the electronic assembly 100 may be seen to include 4 package edge capacitor arrays 114 and each package edge capacitor array 114 may include 3 passive components.

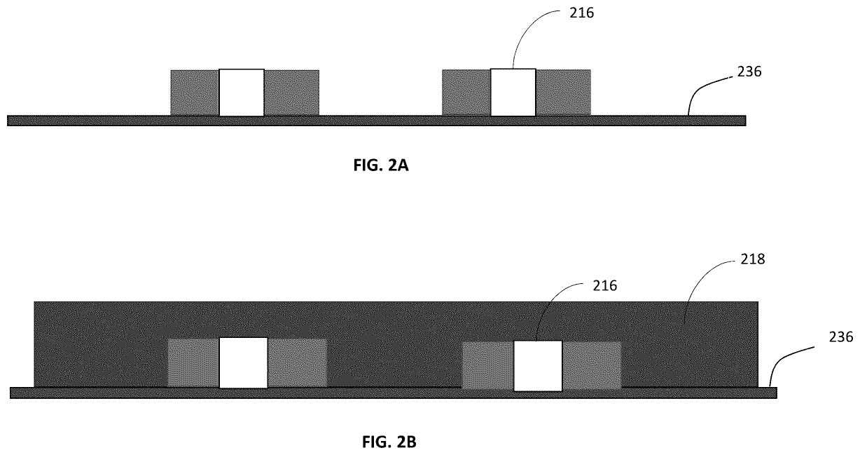

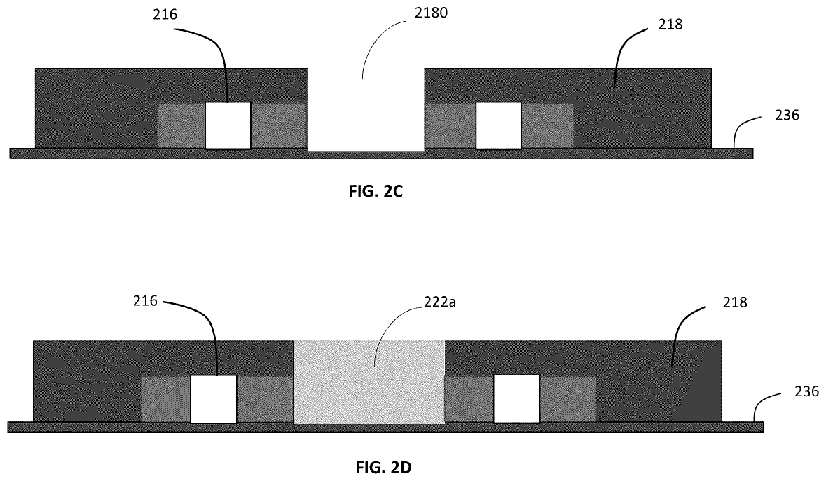

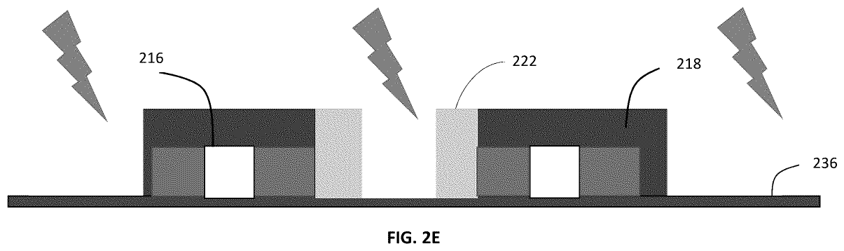

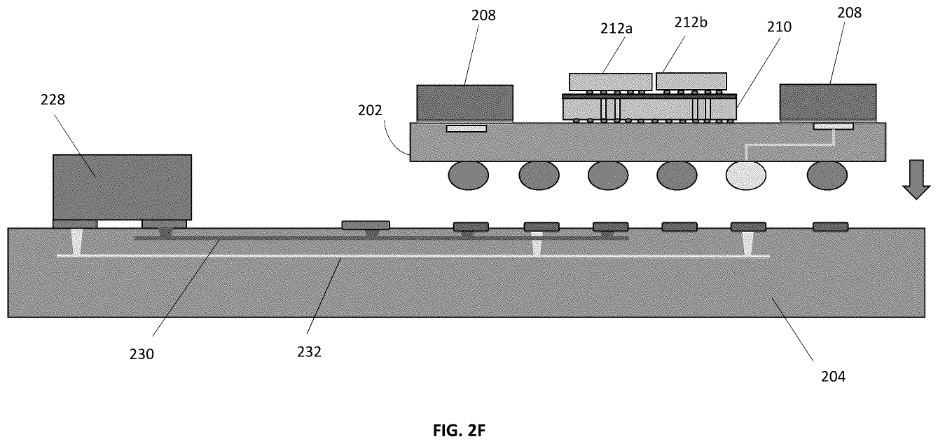

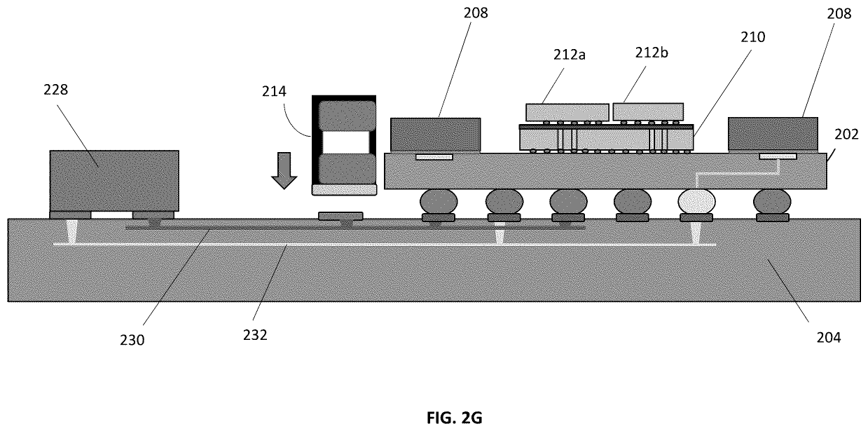

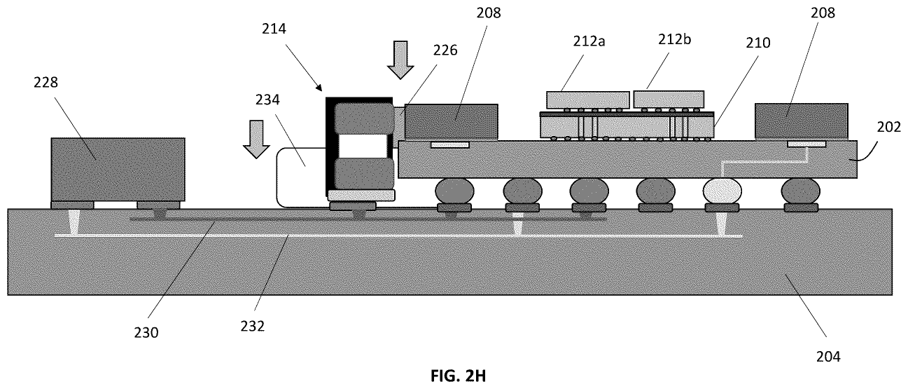

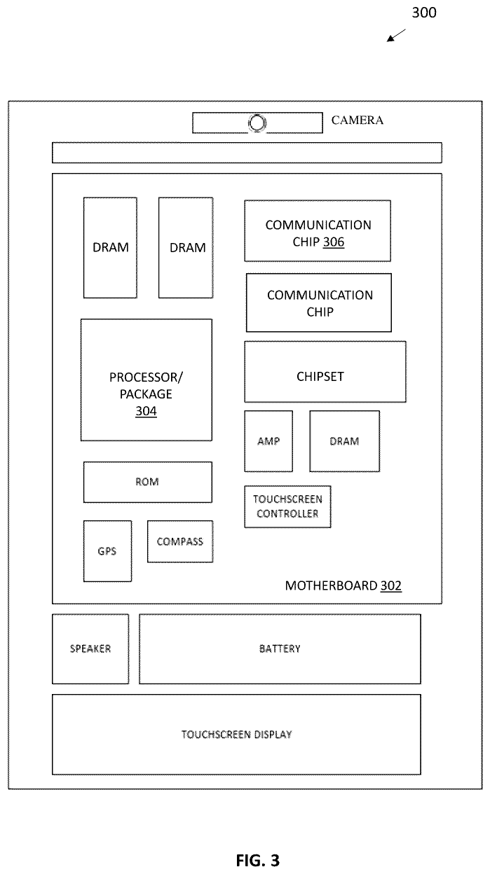

FIGS. 2A through 2H show cross-sectional views directed to an exemplary simplified process flow for forming an electronic assembly according to an aspect that is generally similar to that shown in FIG. 1A of the present disclosure. It is to be noted and appreciated that for simplicity, only one package edge capacitor array may be shown in FIGS. 2A through 2H, even though FIGS. 1A and 1B may illustrate more than one package edge capacitor array. The process flow may be interchangeable.

FIG. 2A shows attachment of capacitor components 216 onto a carrier 236. Conventional techniques may be employed, such as but not limited to, a vacuum pick and place process.

FIG. 2B shows formation of a mold layer 218 over the capacitor components 216. Conventional techniques may be employed, such as but not limited to, a compression, transfer injection molding process.

FIG. 2C shows removal of a portion of the mold layer 218 to form a mold opening 2180 between adjacent capacitor components 216. Conventional techniques may be employed, such as but not limited to, a laser or mechanical drilling, or an etching process.

FIG. 2D shows formation of a terminal contact layer 222a in the mold opening 2180. Conventional techniques may be employed, such as but not limited to, an electroplating, paste printing or grinding process.

FIG. 2E shows formation of a first terminal pad 222 by removing a portion of the terminal contact layer 222a. Portions of the mold layer 218 may also be removed. Conventional techniques may be employed for the removal, such as but not limited to, a drilling or a mechanical sawing process to obtain a plurality of capacitor components 216 embedded in the mold layer 218, thereby forming package edge capacitor arrays 214.

FIG. 2F shows attachment of a package substrate 202 onto a PCB 204. The package substrate 202 may include a stiffener 208, a base die 210, a first and a second chiplets (212a, 212b) disposed thereon as described with respect to FIG. 1A. The PCB 204 may include a voltage regulator 228 and a board routing, solder layer and/or solder ball (collectively, 230) for coupling to the one or more chiplets (212a, 212b) as described with respect to FIG. 1A. The stiffener 208 may be associated with a ground reference voltage (Vss). The stiffener 208 may be coupled to the ground reference voltage (Vss) plane in the package substrate 202 through one or more package contact pads and a conductive layer, e.g., a solder layer or a conductive adhesive layer (collectively, 232). Conventional techniques may be employed, such as but not limited to, a thermal compression bonding or a solder reflow process.

FIG. 2G shows attachment of package edge capacitor arrays 214 onto the PCB 204, adjacent the package substrate 202. Conventional techniques may be employed, such as but not limited to, a thermal compression bonding or solder reflow process.

FIG. 2H shows provision of a corner glue 234 and a second solder layer 226. The second solder layer 226 may be in contact with a side wall of the stiffener 208. The corner glue 234 may encapsulate the package edge capacitor arrays 214. Conventional techniques may be employed, such as but not limited to, a capillary, dispense, jetting, curing, or reflow process.

In an aspect, the package edge capacitor arrays 214 may be attached to the side wall of the stiffener 208 through the second solder layer 226 prior to the attachment of the package substrate 202 onto the PCB 204 (FIG. 2F). Conventional techniques may be employed, such as but not limited to, a thermal compression bonding or solder reflow process. In this aspect, the package edge capacitor arrays 214 and the package substrate 202 may be attached to the PCB 204 simultaneously through, example, a thermal compression bonding or solder reflow process, followed by the provision of the corner glue 234 (FIG. 2H).

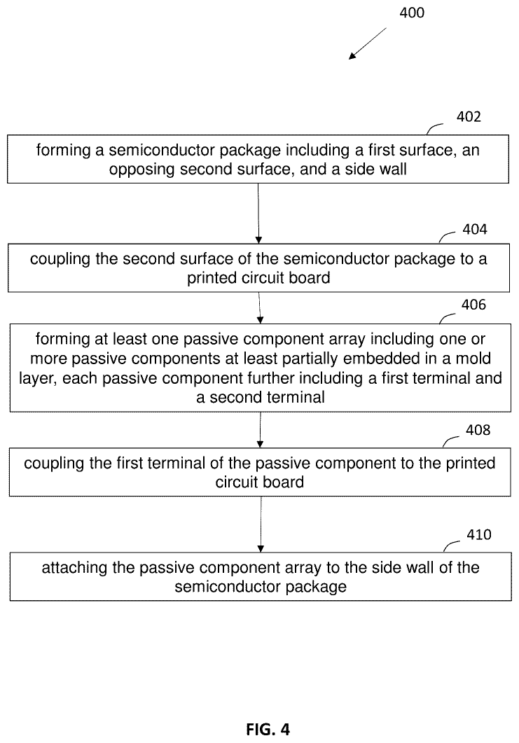

Aspects of the present disclosure may be implemented into a system using any suitable hardware and/or software. FIG. 3 schematically illustrates a computing device 300 that may include an electronic assembly as described herein, in accordance with some aspects. The computing device 300 may house a board such as a motherboard 302. The motherboard 302 may include a number of components, including but not limited to a processor 304 and at least one communication chip 306. The processor 304, which may have the electronic assembly according to the present disclosure, may be physically and electrically coupled to the motherboard 302. In some implementations, the at least one communication chip 306 may also be physically and electrically coupled to the motherboard 302. In further implementations, the communication chip 306 may be part of the processor or package 304.

Depending on its applications, computing device 300 may include other components that may or may not be physically and electrically coupled to the motherboard 302. These other components may include, but are not limited to, volatile memory (e.g. DRAM), non-volatile memory (e.g. ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the processor 304 of the computing device 300 may be packaged in an electronic assembly as described herein, and/or other semiconductor devices may be packaged together in an electronic assembly as described herein.

The communication chip 306 may enable wireless communications for the transfer of data to and from the computing device 300. The term “wireless” and its derivatives may be used to describe circuits, devices, systems, methods, techniques, communications channels, etc. that may communicate data through the use of modulated electromagnetic radiation through a non-solid medium. The term does not imply that the associated devices do not contain any wires, although in some aspects they might not. The communication chip 306 may implement any of a number of wireless standards or protocols, including but not limited to Institute for Electrical and Electronic Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 306 may also operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 306 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 306 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 306 may operate in accordance with other wireless protocols in other aspects.

The computing device 300 may include a plurality of communication chips 306. For instance, a first communication chip 306 may be dedicated to shorter range wireless communications such as Wi-Fi and Bluetooth and a second communication chip 306 may be dedicated to longer range wireless communications such as GPS, EDGE, GPRS, CDMA, WiMAX, LTE, Ev-DO, and others.

In various implementations, the computing device 300 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In an aspect, the computing device 300 may be a mobile computing device. In further implementations, the computing device 300 may be any other electronic device that processes data.

FIG. 4 shows a flow chart illustrating a method 400 of forming an electronic assembly according to an aspect of the present disclosure.

At operation 402, the method 400 may include forming a semiconductor package including a first surface, an opposing second surface, and a side wall.

At operation 404, the method 400 may also include coupling the second surface of the semiconductor package to a printed circuit board.

At operation 406, the method 400 may include forming at least one passive component array including one or more passive components at least partially embedded in a mold layer, each passive component further including a first terminal and a second terminal.

At operation 408, the method 400 may further include coupling the first terminal of the passive component to the printed circuit board.

At operation 410, the method 400 may further include attaching the passive component array to the side wall of the semiconductor package.

It will be understood that the above operations described above relating to FIG. 4 are not limited to this particular order. Any suitable, modified order of operations may be used.

### Examples

Example 1 may include an electronic assembly. The electronic assembly may include a semiconductor package including a first surface, an opposing second surface, and a side wall. The electronic assembly may also include a printed circuit board coupled to the second surface of the semiconductor package. The electronic assembly may further include at least one passive component array including one or more passive components at least partially embedded in a mold layer, each passive component further including a first terminal and a second terminal, wherein the first terminal of the passive component may be coupled to the printed circuit board and the passive component array may be attached to the side wall of the semiconductor package.

Example 2 may include the electronic assembly of example 1 and/or any other example disclosed herein, further including a binding material adhering to a corner of the semiconductor package, wherein the binding material may at least partially encapsulate the passive component array.

Example 3 may include the electronic assembly of example 2 and/or any other example disclosed herein, wherein the semiconductor package may further include a stiffener coupled to the first surface of the semiconductor package, the stiffener including a side surface that may be proximal to the side wall of the semiconductor package, and wherein the second terminal of the passive component may be coupled to the side surface of the stiffener.

Example 4 may include the electronic assembly of example 1 and/or any other example disclosed herein, wherein the electronic assembly may include 4 passive component arrays.

Example 5 may include the electronic assembly of example 1 and/or any other example disclosed herein, wherein each passive component array may include 3 passive components.

Example 6 may include the electronic assembly of example 5 and/or any other example disclosed herein, wherein the one or more passive components may include one or more capacitors.

Example 7 may include the electronic assembly of example 2 and/or any other example disclosed herein, further including a voltage regulator coupled to the printed circuit board, wherein the voltage regulator may be further coupled to the first terminal of the passive component and to the second surface of the semiconductor package.

Example 8 may include the electronic assembly of example 2 and/or any other example disclosed herein, wherein the voltage regulator may be further coupled to the first terminal of the passive component via a board routing in the printed circuit board.

Example 9 may include the electronic assembly of example 1 and/or any other example disclosed herein, wherein the first terminal of the passive component may be associated to a power supply reference voltage (Vcc), and the second terminal of the passive component may be associated to a ground reference voltage (Vss).

Example 10 may include the electronic assembly of example 1 and/or any other example disclosed herein, further including one or more electronic components coupled to the first surface of the semiconductor package, wherein the first terminal of the passive component may be coupled to the one or more electronic components through the second surface of the semiconductor package.

Example 11 may include the electronic assembly of example 10 and/or any other example disclosed herein, wherein the one or more electronic components may include a central processing unit, a system-on-chip, a graphic processing unit, a deep learning processor, or a neural network processor.

Example 12 may include a computing device. The computing device may include a printed circuit board and an electronic assembly coupled to the printed circuit board. The electronic assembly may include a semiconductor package including a first surface, an opposing second surface, and a side wall, wherein the second surface of the semiconductor package may be coupled to the printed circuit board. The electronic assembly may also include at least one passive component array including one or more passive components at least partially embedded in a mold layer, each passive component further including a first terminal and a second terminal, wherein the first terminal of the passive component may be coupled to the printed circuit board and the passive component array may be attached to the side wall of the semiconductor package.

Example 13 may include the computing device of any one of examples 1 to 12 disclosed herein, further including a binding material adhering to a corner of the semiconductor package, wherein the binding material may at least partially encapsulate the passive component array.

Example 14 may include the computing device of any one of examples 1 to 13 disclosed herein, wherein the semiconductor package may further include a stiffener coupled to the first surface of the semiconductor package, the stiffener including a side surface that may be proximal to the side wall of the semiconductor package, and wherein the second terminal of the passive component may be coupled to the side surface of the stiffener.

Example 15 may include the computing device of any one of examples 1 to 14 disclosed herein, wherein the one or more passive components may include one or more capacitors.

Example 16 may include the computing device of any one of examples 1 to 15 disclosed herein, further including a voltage regulator coupled to the printed circuit board, wherein the voltage regulator is further coupled to the first terminal of the passive component and to the second surface of the semiconductor package.

Example 17 may include a method. The method may include forming a semiconductor package including a first surface, an opposing second surface, and a side wall. The method may also include coupling the second surface of the semiconductor package to a printed circuit board. The method may further include forming at least one passive component array including one or more passive components at least partially embedded in a mold layer, each passive component further including a first terminal and a second terminal. The method may also further include coupling the first terminal of the passive component to the printed circuit board and attaching the passive component array to the side wall of the semiconductor package.

Example 18 may include the method of example 17 and/or any other example disclosed herein, further including adhering a binding material to a corner of the semiconductor package to at least partially encapsulate the passive component array.

Example 19 may include the method of example 18 and/or any other example disclosed herein, further including coupling a stiffener to the first surface of the semiconductor package, the stiffener including a side surface that may be proximal to the side wall of the semiconductor package, and coupling the second terminal of the passive component to the side surface of the stiffener.

Example 20 may include the method of example 17 and/or any other example disclosed herein, further including coupling a voltage regulator to the printed circuit board, and further coupling the voltage regulator to the first terminal of the passive component and to the second surface of the semiconductor package.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) used herein may be understood as electrically coupled or as mechanically coupled, e.g., attached or fixed or mounted, or just in contact without any fixation, and it will be understood that both direct coupling and indirect coupling (in other words, coupling without direct contact) may be provided.

While the present disclosure has been particularly shown and described with reference to specific aspects, it should be understood by persons skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. An electronic assembly comprising:
a semiconductor package comprising a first surface, an opposing second surface, and a side wall;
a printed circuit board coupled to the second surface of the semiconductor package; and
at least one passive component array comprising one or more passive components at least partially embedded in a mold layer, each passive component further comprising a first terminal and a second terminal,
wherein the first terminal of the passive component is coupled to the printed circuit board and the passive component array is attached to the side wall of the semiconductor package.

2. The electronic assembly of claim 1, further comprising a binding material adhering to a corner of the semiconductor package, wherein the binding material at least partially encapsulates the passive component array.

3. The electronic assembly of claim 1, wherein the semiconductor package further comprises a stiffener coupled to the first surface of the semiconductor package, the stiffener having a side surface that is proximal to the side wall of the semiconductor package, and wherein the second terminal of the passive component is coupled to the side surface of the stiffener.

4. The electronic assembly of claim 1, wherein the electronic assembly comprises 4 passive component arrays.

5. The electronic assembly of claim 1, wherein each passive component array comprises 3 passive components.

6. The electronic assembly of claim 1, wherein the one or more passive components comprise one or more capacitors.

7. The electronic assembly of claim 1, further comprising a voltage regulator coupled to the printed circuit board, wherein the voltage regulator is further coupled to the first terminal of the passive component and to the second surface of the semiconductor package.

8. The electronic assembly of claim 7, wherein the voltage regulator is further coupled to the first terminal of the passive component via a board routing in the printed circuit board.

9. The electronic assembly of claim 1, wherein the first terminal of the passive component is associated to a power supply reference voltage (Vcc), and the second terminal of the passive component is associated to a ground reference voltage (Vss).

10. The electronic assembly of claim 1, further comprising one or more electronic components coupled to the first surface of the semiconductor package, wherein the first terminal of the passive component is coupled to the one or more electronic components through the second surface of the semiconductor package.

11. The electronic assembly of claim 10, wherein the one or more electronic components comprise a central processing unit, a system-on-chip, a graphic processing unit, a deep learning processor, or a neural network processor.

12. A computing device comprising:
a printed circuit board; and
an electronic assembly coupled to the printed circuit board, the electronic assembly comprising:
a semiconductor package comprising a first surface, an opposing second surface, and a side wall, wherein the second surface of the semiconductor package is coupled to the printed circuit board; and
at least one passive component array comprising one or more passive components at least partially embedded in a mold layer, each passive component further comprising a first terminal and a second terminal,
wherein the first terminal of the passive component is coupled to the printed circuit board and the passive component array is attached to the side wall of the semiconductor package.

13. The computing device of claim 12, further comprising a binding material adhering to a corner of the semiconductor package, wherein the binding material at least partially encapsulates the passive component array.

14. The computing device of claim 12, wherein the semiconductor package further comprises a stiffener coupled to the first surface of the semiconductor package, the stiffener having a side surface that is proximal to the side wall of the semiconductor package, and wherein the second terminal of the passive component is coupled to the side surface of the stiffener.

15. The computing device of claim 12, wherein the one or more passive components comprise one or more capacitors.

16. The computing device of claim 12, further comprising a voltage regulator coupled to the printed circuit board, wherein the voltage regulator is further coupled to the first terminal of the passive component and to the second surface of the semiconductor package.

17. A method comprising:
forming a semiconductor package comprising a first surface, an opposing second surface, and a side wall;
coupling the second surface of the semiconductor package to a printed circuit board;
forming at least one passive component array comprising one or more passive components at least partially embedded in a mold layer, each passive component further comprising a first terminal and a second terminal;
coupling the first terminal of the passive component to the printed circuit board; and
attaching the passive component array to the side wall of the semiconductor package.

18. The method of claim 17, further comprising adhering a binding material to a corner of the semiconductor package to at least partially encapsulate the passive component array.

19. The method of claim 17, further comprising coupling a stiffener to the first surface of the semiconductor package, the stiffener having a side surface that is proximal to the side wall of the semiconductor package, and coupling the second terminal of the passive component to the side surface of the stiffener.

20. The method of claim 17, further comprising coupling a voltage regulator to the printed circuit board, and further coupling the voltage regulator to the first terminal of the passive component and to the second surface of the semiconductor package.
